(19) United States
(12) Patent Application Publication
(10) Pub. No.: US 2012/0188787 A1
(43) Pub. Date: Jul. 26, 2012

(54) SYSTEM FOR ILLUMINATING A VEHICLE INTERIOR ASSEMBLY

(75) Inventors: Steve G. Schultz, Holland, MI (US); Timothy J. Borgeson, Hudsonville, MI (US); Johnathan M. Frens, Hudsonville, MI (US)

(73) Assignee: Johnson Controls Technology Company, Holland, MI (US)

(21) Appl. No.: 13/012,543

(22) Filed: Jan. 24, 2011

(51) Int. Cl. H01L 33/02; G02B 6/00; H05K 13/04; B23P 17/00; H05K 3/30; B60R 13/02; G02B 6/02

(52) U.S. Cl. 362/555; 296/1.08; 362/551; 29/428; 29/832; 29/460

(57) ABSTRACT

A vehicle interior assembly includes a light pipe that is concealed by at least one element of the assembly and is configured to illuminate a recess disposed adjacent to a display.

### BACKGROUND

The invention relates generally to vehicle interior assemblies, and more specifically, to a system for illuminating a vehicle interior assembly.

A variety of decorative or aesthetic lighting systems may be employed throughout an interior of a vehicle. For example, certain instrument panels (e.g., instrument gauge cluster modules, driver information electronic sub-assemblies, etc.) may include vehicle interior lighting assemblies configured to illuminate individual gauges, groups of gauges and/or the perimeter of the instrument panel. Other instrument panels may include a lighting assembly configured to illuminate a perimeter of a graphical display. Furthermore, additional displays and/or gauges may be located within other areas of the vehicle interior, such as the front console and/or the headrest of a seat, for example. Such displays and/or gauges may include interior lighting assemblies configured to illuminate various regions of the displays and/or gauges.

Certain vehicle interior lighting assemblies are used to provide a lighted fade effect around a perimeter of a gauge or display. For example, a lighted fade effect may be used adjacent to a perimeter of a speedometer and/or tachometer in a vehicle instrument cluster. Such an effect may provide an aesthetically pleasing appearance and/or may visually enhance the interior environment of the vehicle. Unfortunately, various interferences and ergonomic constraints may limit the available space for such lighting assemblies. For example, sufficient space may not be available to place a light source behind the illuminated region.

### BRIEF DESCRIPTION OF THE INVENTION

The present invention relates to a vehicle interior assembly including a light pipe configured to illuminate a recess at least partially disposed adjacent to a display, where the light pipe is concealed by at least one element of the vehicle interior assembly.

The present invention also relates to a vehicle interior assembly including a trim component and a bezel that includes a recess at least partially disposed adjacent to a perimeter of the display. The vehicle interior assembly further includes a light pipe disposed behind the trim component and configured to illuminate the recess.

The present invention further relates to a method for manufacturing a vehicle interior assembly. The method includes concealing a light pipe within a recess at least partially disposed adjacent to a display such that the light pipe illuminates the recess. The method further includes disposing a light source at an end of the light pipe such that the light source illuminates the light pipe. Additionally, the method includes disposing a light-diffusing coating onto the light pipe, the recess or a combination thereof, and disposing the light pipe behind a trim component.

### DRAWINGS

FIG. 1 is a perspective view of an exemplary vehicle that may include a system for illuminating a vehicle interior assembly.

FIG. 2 is a perspective view of a part of the interior of the vehicle of FIG. 1.

FIG. 3 is a front view of an exemplary instrument panel including multiple recesses disposed adjacent to respective displays.

FIG. 4 is a front view of an embodiment of a vehicle interior assembly including a recess illuminated by a light pipe, and a trim component positioned to conceal the light pipe.

FIG. 5 is an exploded perspective view of the vehicle interior assembly of FIG. 4.

FIG. 6 is a schematic diagram of an exemplary vehicle interior assembly including a display, a light pipe disposed about the display, and a light source configured to illuminate the light pipe.

FIG. 7 is a flow diagram of an exemplary method for manufacturing a vehicle interior assembly to illuminate a recess disposed adjacent to a display.

### DETAILED DESCRIPTION

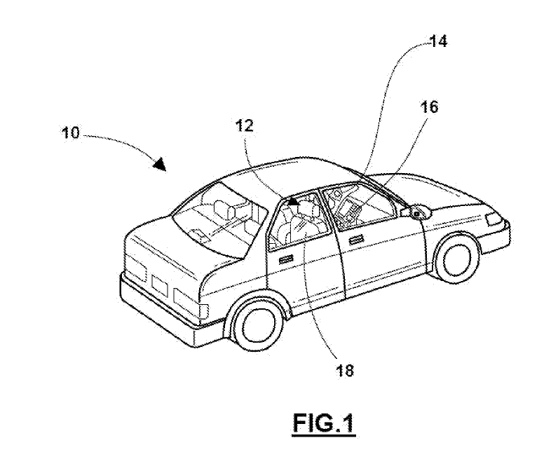

FIG. 1 is a perspective view of an exemplary vehicle 10 that includes a system for illuminating a vehicle interior assembly. As illustrated, the vehicle 10 includes an interior 12 having an instrument panel 14 (e.g., instrument gauge cluster module, driver information electronic sub-assembly, etc.), a front console 16 and seats 18. A variety of vehicle interior assemblies may be employed throughout the vehicle interior 12. For example, the instrument panel 14 may include vehicle interior assemblies having illuminated recesses disposed about individual gauges, groups of gauges and/or the perimeter of the instrument panel 14. Other instrument panels 14 may include a vehicle interior assembly having a graphical display and an illuminated recess disposed adjacent to the display. Furthermore, additional displays and/or gauges may be located within other areas of the vehicle interior, such as the front console 16 and/or the headrest of the seat 18, for example. Interior assemblies supporting such displays and/or gauges may also include illuminated recessed to enhance the appearance of the displays and/or gauges.

As discussed in further detail below, at least one vehicle interior assembly within the vehicle interior 12 is illuminated to provide accent lighting. For example, the instrument panel 14 may include a interior assembly having a display and an illuminated recess disposed about a perimeter of the display. An exemplary vehicle interior assembly includes a light pipe configured to illuminate the recess and a trim component positioned to conceal the light pipe from vehicle occupants. The vehicle interior assembly may use diffused lighting in a low profile configuration to illuminate the recess, thereby providing the appearance of an integrated and flush assembly. Furthermore, the vehicle interior assembly may provide a lighted fade effect or a three dimensional floating effect to enhance the visual appeal of the graphical display.

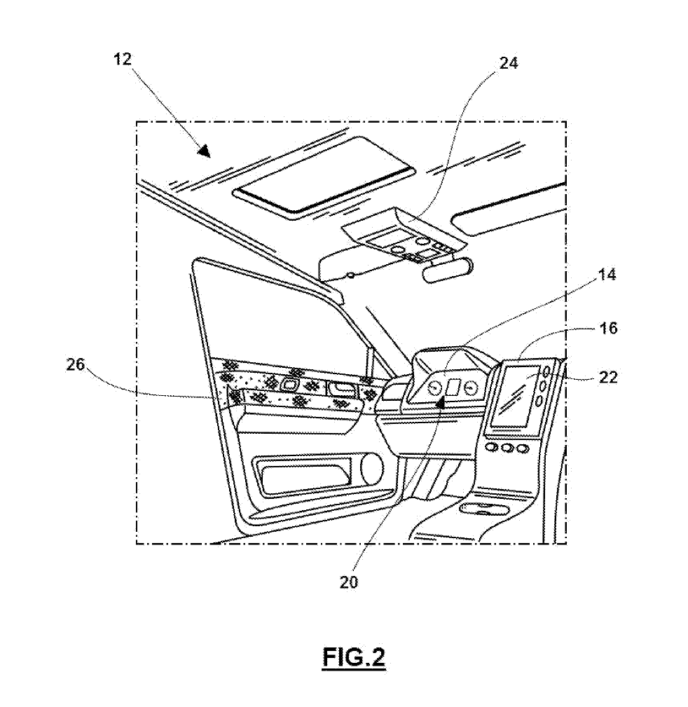

FIG. 2 is a perspective view of a part of the interior 12 of the vehicle 10 of FIG. 1. As illustrated, the instrument panel 14 includes a cluster of electronic sub-assemblies 20. As discussed in detail below, the electronic sub-assemblies 20 may include electromechanical gauges and/or graphical displays, for example. Each sub-assembly within the instrument panel 14 may include a lighting assembly disposed adjacent to the perimeter of the sub-assembly. More particularly, the lighting assembly defines a recess and includes a light pipe configured to illuminate the recess. In addition, a lighting assembly of a similar configuration may be disposed about a group of sub-assemblies and/or about the perimeter of the instrument panel 14. At least one lighting assembly within the instrument panel 14 may provide a lighted effect using a low profile configuration. In the illustrated embodiment, the front console 16 includes another electronic display 22 which may include a lighting assembly disposed about the perimeter of the display 22. Furthermore, an overhead console 24 and/or a door panel 26 may include electronic displays having lighting assemblies of the type discussed in this disclosure. One or more of these lighting assemblies may provide accent or fade lighting using a concealed light pipe configured to illuminate a recess within the lighting assembly.

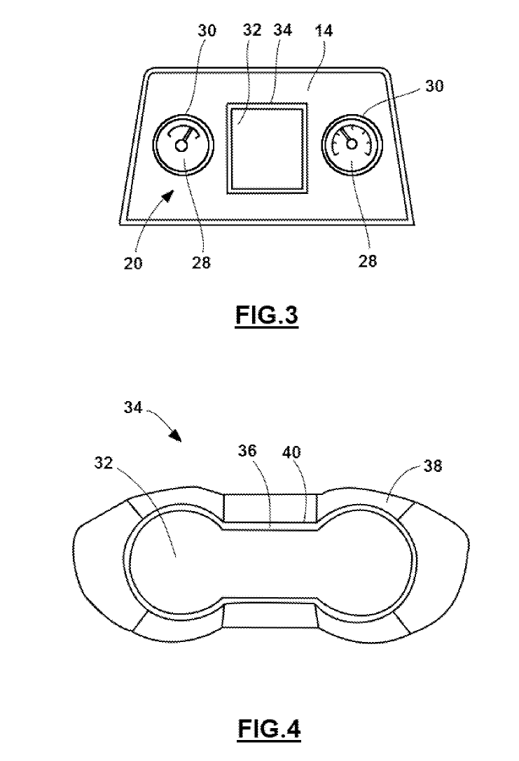

FIG. 3 is a front view of an exemplary instrument panel 14 including multiple lighting assemblies. In the illustrated embodiment, the instrument panel 14 includes a cluster of electronic sub-assemblies 20, such as the illustrated electromechanical gauges 28. The electromechanical gauges 28 are configured to receive a signal indicative of a value of a vehicle parameter, and to convey the value to a vehicle operator. For example, the electromechanical gauges 28 may be configured to display a value indicative of fuel quantity, vehicle speed, coolant temperature, oil temperature, oil pressure, crankshaft rotation rate and/or other parameters associated with operation of the vehicle 10. As illustrated, a lighting assembly 30 is disposed adjacent to each electromechanical gauge 28. As mentioned above, the lighting assembly 30 may include a light pipe configured to illuminate a recess formed within the lighting assembly 30.

In addition, the cluster of electronic sub-assemblies 20 includes a graphical display 32. In certain embodiments, the graphical display 32 includes a liquid crystal display (LCD), e.g., thin film transistor (TFT) display, configured to present various vehicle parameters and/or navigational information to a vehicle operator. For example, the graphical display 32 may be configured to display numerical and/or graphical representations of values indicative of fuel quantity, vehicle speed, coolant temperature, oil temperature, oil pressure, crankshaft rotation rate and/or other parameters associated with operation of the vehicle 10. In addition, the graphical display 32 may be configured to present two-dimensional or three-dimensional information associated with operation of the vehicle entertainment system, environmental control system, and/or navigational system (e.g., a moving map display). Similar to the electromechanical gauges 28, a lighting assembly 34 is disposed adjacent to the graphical display 32. As discussed in detail below, the lighting assemblies 30 and 34 may use diffused lighting to provide accent lighting about a perimeter of the gauges 28 and the graphical display 32. Furthermore, the lighting assemblies 30 and 34 may be constructed using a low profile configuration to provide a flush and integrated appearance. The low profile configuration may further provide a lighted fade or three dimensional floating effect. While an instrument panel 14 is described above, it should be appreciated that a vehicle interior assembly using a light pipe disposed adjacent to a recess and having a low profile configuration may be employed within alternative vehicle interior assemblies, such as front consoles 16, seats 18 and/or door panels 26, for example.

FIG. 4 is a front view of an exemplary embodiment of a lighting assembly 34 disposed adjacent to a graphical display 32. As shown in FIG. 4, the lighting assembly 34 includes a trim component 36 and a bezel 38 having a recess 40. As discussed in further detail below, various individual or conjunctive configurations of the trim component 36 and the bezel 38 may define the recess 40. For example, the recess 40 may be formed by a depression in the bezel 38. Alternatively, the recess 40 may be formed by the suspension of a portion of the trim component 36 over the bezel 38. Furthermore, a combination of the structures of the trim component 36 and bezel 38 may form the recess 40. The trim component 36 and the bezel 38 may be constructed from various similar or differing solid materials. For example, the trim component 36 and/or the bezel 48 may be constructed from metal, plastic, or other structural material. As discussed in further detail below, in one embodiment, a light pipe is disposed adjacent to the recess and is concealed by the trim component 36. Alternatively, in another embodiment, the light pipe may be disposed adjacent to the recess and concealed by the bezel 38. The light pipe may also be concealed by both the trim component 36 and the bezel 38.

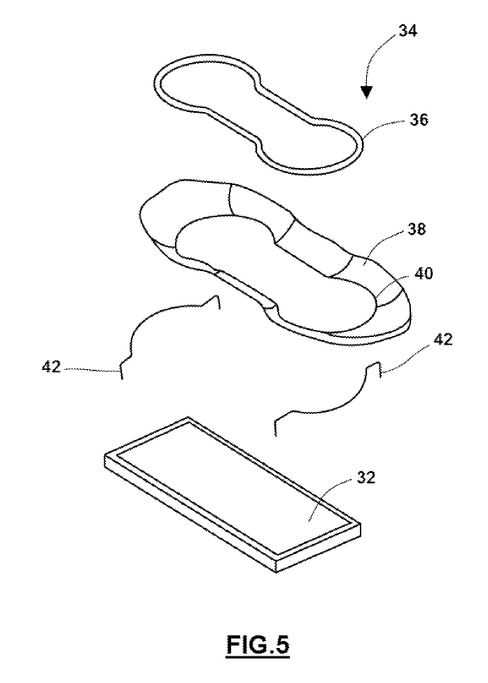

FIG. 5 is an exploded perspective view of a lighting assembly 34 disposed adjacent to a graphical display 32. The lighting assembly 34 includes a trim component 36, a bezel 38, a recess 40 and a light pipe 42. In certain embodiments, the lighting assembly 34 may include more than one light pipe 42 to provide a desired lighting effect about the graphical display 32. As mentioned above, the trim component 36 and the bezel 38 may be constructed from solid materials such as metal or plastic. Additionally, the light pipe 42 may be constructed from a fiber optic material. For example, certain embodiments may include a light pipe 42 made from a clear molded optical grade plastic. Furthermore, the light pipe 42 may have a treated surface to provide a desired lighting effect. For example, the light pipe 42 may have a textured or “frosted” surface coating to provide a faded light effect. It should be appreciated that, in alternative embodiments, the light pipe 42 may be treated with other surface treatments such as surface molding, printed fade, among others, to provide other desired lighting effects.

As illustrated, the light pipe 42 is shaped to fit within the recess 40 and is disposed adjacent to the graphical display 32. In should be appreciated that, in alternative embodiments, the light pipe 42 may be any suitable shape to provide a desired lighting effect. The light pipe 42 may be constructed from a fiber optic material to facilitate illumination of the recess 40 by a remote light source, thereby obviating the use of a light source disposed directly underneath the graphical display 32. As a result, the vehicle interior assembly 34 may have a low profile configuration that enables the lighting assembly 34 to be placed directly above the graphical display 32. Consequently, the lighting assembly 34 provides the appearance that the graphical display 32, the trim component 36 and the bezel 38 are an integrated unit.

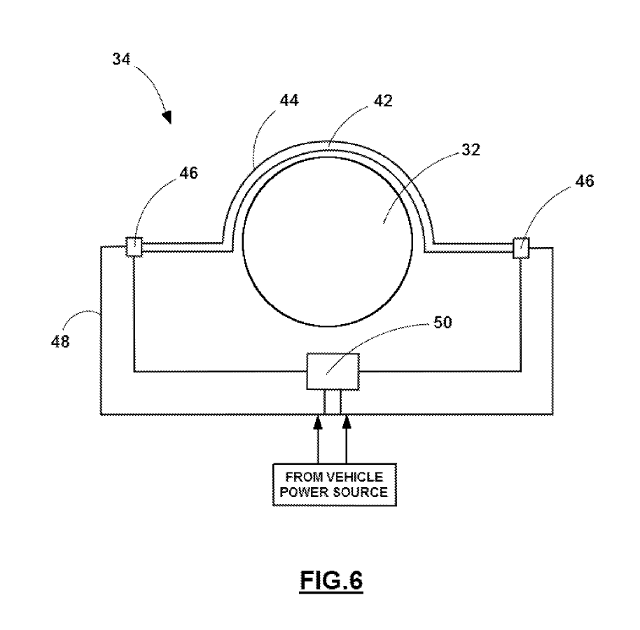

FIG. 6 is a schematic of an exemplary lighting assembly 34 disposed adjacent to a graphical display 32. In particular, the lighting assembly includes a light pipe 42 with a surface treatment 44 positioned at least partially about a perimeter of the graphical display 32. The illustrated embodiment further includes a light source 46 disposed at each end of the light pipe 42. In other embodiments, the light source 46 may be disposed at only one end of the light pipe 42. Furthermore, the vehicle interior assembly 34 includes a circuit assembly 48, such as a printed circuit board. The light source 46 is mounted on and electrically coupled to the circuit assembly 48. In some embodiments, there may be multiple light sources 46 mounted on a single circuit assembly 48. In other embodiments, each light source 46 may be mounted on separate circuit assemblies 48. The illustrated circuit assembly 48 further includes a voltage regulator 50 configured to drive the light source 46. In the illustrated embodiment, the voltage regulator 50 is configured to receive electrical power from a vehicle power source, and to provide a desired voltage to the light sources 46. As discussed above, it should be appreciated that the light source 46 is disposed in a location that is not directly underneath the graphical display 32 to facilitate a low profile configuration of the lighting assembly 34.

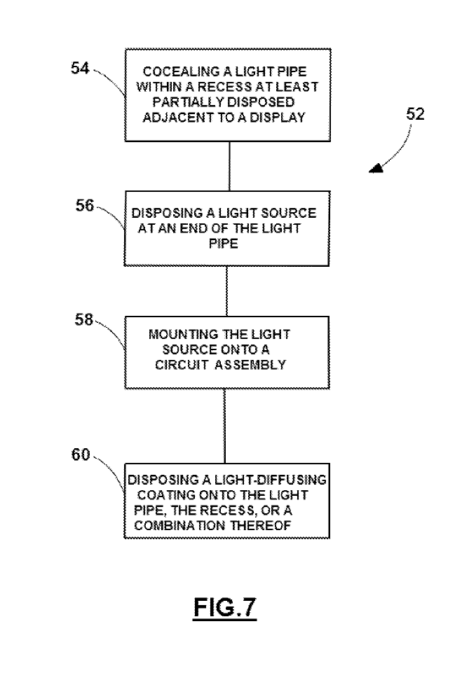

FIG. 7 is a flow diagram of an exemplary method 52 for illuminating a recess disposed adjacent to a display. First, as represented by block 54, a light pipe 42 is concealed within a recess 40 disposed adjacent to a display 32. For example, the light pipe 42 may be concealed behind a trim component 36 or a bezel 38. Next, a light source 46 is disposed at the end of the light pipe 42, as represented by block 56. In some embodiments, a light source 46 may be disposed at both ends of the light pipe 42. Thereafter, as represented by block 58, the light source 46 is mounted onto a circuit assembly 48. For example, the light source 46 may be mounted onto a printed circuit board. Further, a light-diffusing coating 44 is then disposed onto the light pipe 42, the recess 40 or a combination thereof, as represented by block 60. As a result, the light emitted from the light source 46 will illuminate the light pipe 42 and provide the desired lighting effect within the recess 40.

While only certain features and embodiments of the invention have been illustrated and described, many modifications and changes may occur to those skilled in the art (e.g., variations in sizes, dimensions, structures, shapes and proportions of the various elements, values of parameters (e.g., temperatures, pressures, etc.), mounting arrangements, use of materials, colors, orientations, etc.) without materially departing from the novel teachings and advantages of the subject matter recited in the claims. The order or sequence of any process or method steps may be varied or re-sequenced according to alternative embodiments. It is, therefore, to be understood that the appended claims are intended to cover all such modifications and changes as fall within the true spirit of the invention. Furthermore, in an effort to provide a concise description of the exemplary embodiments, all features of an actual implementation may not have been described (i.e., those unrelated to the presently contemplated best mode of carrying out the invention, or those unrelated to enabling the claimed invention). It should be appreciated that in the development of any such actual implementation, as in any engineering or design project, numerous implementation specific decisions may be made. Such a development effort might be complex and time consuming, but would nevertheless be a routine undertaking of design, fabrication, and manufacture for those of ordinary skill having the benefit of this disclosure, without undue experimentation.

1. A vehicle interior assembly, comprising:
a light pipe configured to illuminate a recess disposed adjacent to a display, wherein the light pipe is concealed by at least one element of the vehicle interior assembly.

2. The vehicle interior assembly of claim 1, wherein the at least one element comprises a trim component.

3. The vehicle interior assembly of claim 2, wherein the display comprises an electromechanical gauge.

4. The vehicle interior assembly of claim 2, wherein the display comprises a liquid crystal display.

5. The vehicle interior assembly of claim 1, wherein the light pipe is constructed from a fiber optic material.

6. The vehicle interior assembly of claim 1, comprising a first light source disposed at a first end of the light pipe, wherein the first light source is configured to illuminate the light pipe.

7. The vehicle interior assembly of claim 6, comprising a second light source disposed at a second end of the light pipe, wherein the second light source is configured to illuminate the light pipe.

8. The vehicle interior assembly of claim 6, wherein the first light source comprises a light emitting diode.

9. The vehicle interior assembly of claim 6, comprising a printed circuit board configured to drive the first light source.

10. The vehicle interior assembly of claim 9, wherein the first light source is mounted to the printed circuit board.

11. A vehicle interior assembly, comprising:
a bezel having a recess disposed adjacent to a display;
a trim component disposed adjacent to the recess; and
a light pipe disposed behind the trim component and configured to illuminate the recess.

12. The vehicle interior assembly of claim 11, comprising a light source disposed at an end of the light pipe, and configured to illuminate the light pipe.

13. The vehicle interior assembly of claim 12, wherein the light source is a light emitting diode.

14. The vehicle interior assembly of claim 11, wherein the display is a liquid crystal display.

15. A method for manufacturing a vehicle interior assembly, comprising:
concealing a light pipe within a recess disposed adjacent to a display such that the light pipe illuminates the recess.

16. The method of claim 15, comprising disposing a light source at an end of the light pipe such that light emitted from the light source illuminates the light pipe.

17. The method of claim 16, comprising mounting the light source onto a printed circuit board such that the light source is electrically coupled to the printed circuit board.

18. The method of claim 16, wherein the light source comprises a light emitting diode.

19. The method of claim 15, comprising disposing a light-diffusing coating onto the light pipe, the recess, or a combination thereof.

20. The method of claim 15, comprising disposing the light pipe behind a trim component.
